(19) United States
(12) Patent Application Publication
(10) Pub. No.: US 2014/0254113 A1
(43) Pub. Date: Sep. 11, 2014

(54) METHOD OF PROVIDING AN ELECTRONIC DEVICE STRUCTURE AND RELATED ELECTRONIC DEVICE STRUCTURES

(71) Applicants: Emmett Howard, Gilbert, AZ (US); Douglas E. Loy, Chandler, AZ (US); Nicholas Munizza, Gilbert, AZ (US)

(72) Inventors: Emmett Howard, Gilbert, AZ (US); Douglas E. Loy, Chandler, AZ (US); Nicholas Munizza, Gilbert, AZ (US)

(73) Assignee: Arizona Board of Regents, a Body Corporate of the State of Arizona Acting for and on Behalf of Arizo, Scottsdale, AZ (US)

(21) Appl. No.: 14/288,771

(22) Filed: May 28, 2014

Related U.S. Application Data
(63) Continuation of application No. PCT/US12/66833, filed on Nov. 28, 2012.
Application No. PCT/US12/66833 is a continuation-in-part of application No. 13/913,141, filed on Jun. 7, 2013.
Application No. 13/913,141 is a continuation of application No. 13/118,225, filed on May 27, 2011, now Pat. No. 8,481,859.
Application No. 13/118,225 is a continuation of application No. PCT/US09/66259, filed on Dec. 1, 2009.
(60) Provisional application No. 61/564,535, filed on Nov. 29, 2011.
(60) Provisional application No. 61/230,051, filed on Jul. 30, 2009.
(60) Provisional application No. 61/182,464, filed on May 29, 2009.
(60) Provisional application No. 61/119,217, filed on Dec. 2, 2008.

(51) Int. Cl. H05K 1/03; H05K 3/00; H05K 1/02

(52) U.S. Cl. CPC H05K 1/0393; H05K 1/028; H05K 1/03; H05K 3/0058; H05K 3/007
USPC 361/749; 428/430; 428/412; 428/441; 428/435; 428/426; 156/60; 156/247; 156/250; 156/281

(57) ABSTRACT

Some embodiments include a method of providing an electronic device structure. Other embodiments for related methods and electronic device structures are also disclosed.

### CROSS-REFERENCE TO RELATED APPLICATIONS

This application is a continuation application of PCT Application No. PCT/US2012/066833, filed Nov. 28, 2012, and is a continuation-in-part application of U.S. patent application Ser. No. 13/913,141, filed Jun. 7, 2013.

PCT Application No. PCT/US2012/066833 claims the benefit of U.S. Provisional Patent Application No. 61/564,535, filed Nov. 29, 2011.

Meanwhile, U.S. patent application Ser. No. 13/913,141 is a continuation application of U.S. patent application Ser. No. 13/118,225, filed May 27, 2011, and U.S. Non-Provisional application Ser. No. 13/118,225 is a continuation application of PCT Application No. PCT/US2009/066259, filed on Dec. 1, 2009. PCT Application No. PCT/US2009/066259 claims the benefit of (a) U.S. Provisional Application 61/230,051, filed Jul. 30, 2009, (b) U.S. Provisional Application 61/182,464, filed May 29, 2009, and (c) U.S. Provisional Application 61/119,217, filed Dec. 2, 2008.

PCT Application No. PCT/US2012/066833, U.S. Provisional Patent Application No. 61/564,535, U.S. patent application Ser. No. 13/913,141, U.S. patent application Ser. No. 13/118,225, PCT Application No. PCT/US2009/066259, U.S. Provisional Application 61/230,051, U.S. Provisional Application 61/182,464, and U.S. Provisional Application 61/119,217 are incorporated herein by reference in their entirety.

### STATEMENT REGARDING FEDERALLY SPONSORED RESEARCH OR DEVELOPMENT

This invention was made with government support under W911NF-04-2-0005 awarded by the Army Research Office. The government has certain rights in the invention.

### FIELD OF THE INVENTION

This invention relates generally to methods of providing electronic device structures, and relates more particularly to such methods for coupling and decoupling flexible substrates from rigid substrates and related methods and electronic device strictures.

### DESCRIPTION OF THE BACKGROUND

Although flexible electronic devices may be used in a variety of ways that rigid electronic devices may not, manufacturing flexible electronic devices can be difficult and/or expensive. However, the difficulty and/or expense of manufacturing flexible electronic devices can be reduced by coupling flexible substrates to rigid substrates such that electronic devices can be manufactured on the flexible substrates using conventional equipment and/or techniques for rigid electronic device manufacturing. Accordingly, a need or potential for benefit exists for a method of decoupling the flexible substrates from the rigid substrates after manufacturing the electronic devices and for methods and electronic device structures related thereto.

### BRIEF DESCRIPTION OF THE DRAWINGS

To facilitate further description of the embodiments, the following drawings are provided in which:

FIG. 1 illustrates a flow chart for an embodiment of a method of providing one or more electronic devices;

FIG. 2 illustrates an exemplary procedure of providing a carrier substrate, according to the embodiment of FIG. 1;

FIG. 3 illustrates an exemplary process of treating the carrier substrate, according to the embodiment of FIG. 1;

FIG. 4 illustrates a partial cross-sectional view of an exemplary electronic device structure after providing a carrier substrate, according to the embodiment of FIG. 1;

FIG. 5 illustrates an exemplary procedure of providing an intermediate substrate, according to the embodiment of FIG. 1;

FIG. 6 illustrates a partial cross-sectional view of the electronic device structure of FIG. 4 after applying and/or depositing a first adhesive at a first carrier substrate surface of the carrier substrate of FIG. 4, according to the embodiment of FIG. 1;

FIG. 7 illustrates an exemplary procedure of interposing the intermediate substrate of FIG. 5 between the carrier substrate of FIG. 2 and a flexible substrate in order to couple the flexible substrate to the carrier substrate, according to the embodiment of FIG. 1;

FIG. 8 illustrates an exemplary process of coupling a first intermediate substrate surface of the intermediate substrate of FIG. 5 to the carrier substrate of FIG. 2 with a first adhesive, according to the embodiment of FIG. 1;

FIG. 9 illustrates a partial cross-sectional view of electronic device structure of FIG. 4 after coupling a first intermediate substrate surface of an intermediate substrate to the first carrier substrate surface of the carrier substrate of FIG. 4 with the first adhesive of FIG. 6, according to the embodiment of FIG. 1;

FIG. 10 illustrates an exemplary process of coupling a second intermediate substrate surface of the intermediate substrate of FIG. 5 to the first flexible substrate with a second adhesive, according to the embodiment of FIG. 1;

FIG. 11 illustrates a partial cross-sectional view of the electronic device structure of FIG. 4 after applying and/or depositing a second adhesive at a second intermediate substrate surface of the intermediate substrate of FIG. 9 and after coupling the first intermediate substrate surface of the intermediate substrate of FIG. 9 to the first carrier substrate surface of the carrier substrate of FIG. 4 with the first adhesive of FIG. 6, according to the embodiment of FIG. 1;

FIG. 12 illustrates a cross-sectional view of the electronic device structure of FIG. 4 after coupling the second intermediate substrate surface of FIG. 11 of the intermediate substrate of FIG. 9 to a first flexible substrate surface of a flexible substrate with the second adhesive of FIG. 11, after applying and/or depositing the second adhesive at the second intermediate substrate surface, and after coupling the first intermediate substrate surface of the intermediate substrate of FIG. 9 to the first carrier substrate surface of the carrier substrate of FIG. 4 with the first adhesive of FIG. 6, according to the embodiment of FIG. 1;

FIG. 13 illustrates a cross-sectional view of the electronic device structure of FIG. 4 after interposing the intermediate substrate of FIG. 9 between the carrier substrate of FIG. 4 and the flexible substrate of FIG. 12 and after forming electronic device(s) over a second flexible substrate surface of the flexible substrate, according to the embodiment of FIG. 1;

FIG. 14 illustrates a cross-sectional view of the electronic device structure of FIG. 4 after the forming electronic device(s) of FIG. 13 over the second flexible substrate surface of FIG. 12 and after decoupling the first intermediate substrate surface of the intermediate substrate of FIG. 9 from the carrier substrate of FIG. 4, according to the embodiment of FIG. 1; and

FIG. 15 illustrates a cross-sectional view of the electronic device structure of FIG. 4 after forming the electronic device(s) of FIG. 13 over the second flexible substrate surface of FIG. 12, after decoupling the first intermediate substrate surface of intermediate substrate of FIG. 9 from the carrier substrate of FIG. 4, and after decoupling the second intermediate substrate surface of FIG. 11 from the first flexible substrate surface of the flexible substrate of FIG. 12, according to the embodiment of FIG. 1.

For simplicity and clarity of illustration, the drawing figures illustrate the general manner of construction, and descriptions and details of well-known features and techniques may be omitted to avoid unnecessarily obscuring the invention. Additionally, elements in the drawing figures are not necessarily drawn to scale. For example, the dimensions of some of the elements in the figures may be exaggerated relative to other elements to help improve understanding of embodiments of the present invention. The same reference numerals in different figures denote the same elements.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Furthermore, the terms “include,” and “have,” and any variations thereof, are intended to cover a non-exclusive inclusion, such that a process, method, system, article, device, or apparatus that comprises a list of elements is not necessarily limited to those elements, but may include other elements not expressly listed or inherent to such process, method, system, article, device, or apparatus.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein.

The terms “couple,” “coupled,” “couples,” “coupling,” and the like should be broadly understood and refer to connecting two or more elements or signals, electrically, mechanically and/or otherwise. Two or more electrical elements may be electrically coupled together, but not be mechanically or otherwise coupled together; two or more mechanical elements may be mechanically coupled together, but not be electrically or otherwise coupled together; two or more electrical elements may be mechanically coupled together, but not be electrically or otherwise coupled together. Coupling may be for any length of time, e.g., permanent or semi-permanent or only for an instant.

“Electrical coupling” and the like should be broadly understood and include coupling involving any electrical signal, whether a power signal, a data signal, and/or other types or combinations of electrical signals. “Mechanical coupling” and the like should be broadly understood and include mechanical coupling of all types.

The absence of the word “removably,” “removable,” and the like near the word “coupled,” and the like does not mean that the coupling, etc. in question is or is not removable.

The term “CTE matched material” as used herein means a material that has a coefficient of thermal expansion (CTE) which differs from the CTE of a reference material by less than about 20 percent (%). In some embodiments, the CTEs differ by less than about 10%, 5%, 3%, or 1%.

### DETAILED DESCRIPTION OF EXAMPLES OF EMBODIMENTS

Some embodiments include a method of providing one or more electronic devices. The method can comprise: providing a carrier substrate; providing an intermediate substrate comprising a first intermediate substrate surface and a second intermediate substrate surface opposite the first intermediate substrate surface; providing a flexible substrate comprising a first flexible substrate surface and a second flexible substrate surface opposite the first flexible substrate surface; coupling the first intermediate substrate surface to the carrier substrate with a first adhesive; and coupling the second intermediate substrate surface to the first flexible substrate surface with a second adhesive.

Various embodiments include a method of providing one or more electronic devices. The method can comprise: providing a carrier substrate; providing a flexible substrate; and interposing a ruggedization film between the carrier substrate and the flexible substrate in order to couple the flexible substrate to the carrier substrate. The ruggedization film can be configured to substantially relieve stress formed at the flexible substrate when the flexible substrate is decoupled from the carrier substrate.

Further embodiments include an electronic device structure. The electronic device structure comprises an intermediate substrate. The substrate comprises a first intermediate substrate surface and a second intermediate substrate surface opposite the first intermediate substrate surface. Meanwhile, the first intermediate substrate surface can be configured to be coupled to a carrier substrate by a first adhesive. The electronic device structure further comprises a flexible substrate. The flexible substrate comprises a first flexible substrate surface and a second flexible substrate surface opposite the first flexible substrate surface. The first flexible substrate surface can be configured to be coupled to the second intermediate substrate surface by a second adhesive, and the second flexible substrate surface can be configured such that one or more electronic devices can be formed over the second flexible substrate surface when the first intermediate substrate surface is coupled to the carrier substrate and when the first flexible substrate surface is coupled to the second intermediate substrate surface.

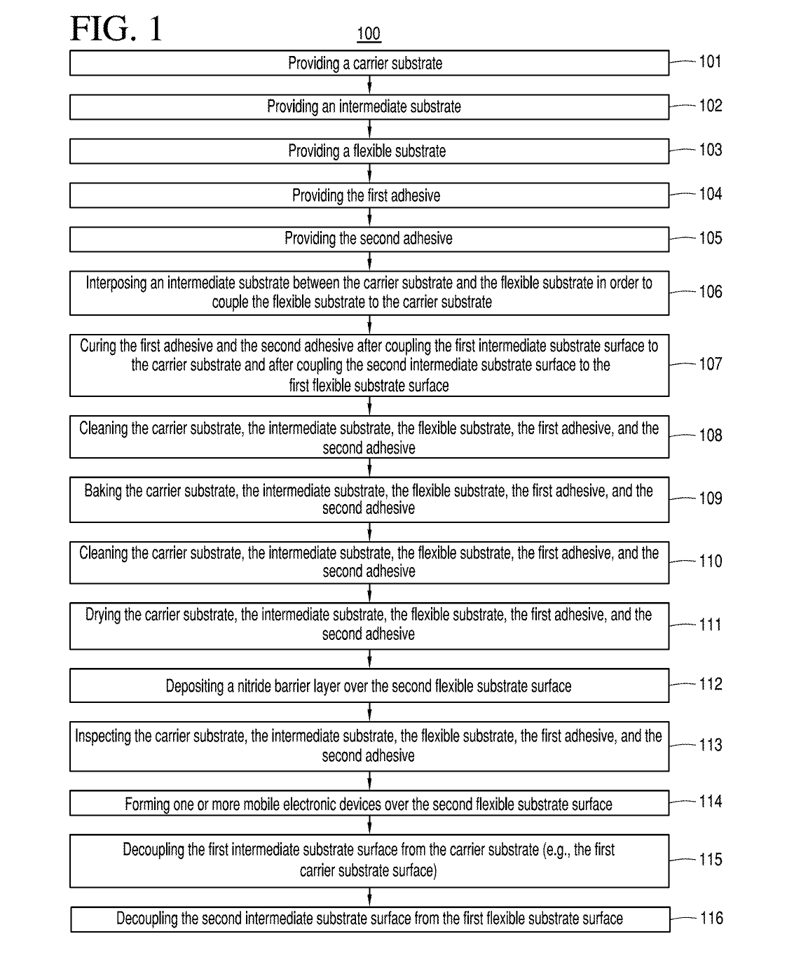

FIG. 1 illustrates a flow chart for an embodiment of method 100 of providing one or more electronic devices. Method 100 is merely exemplary and is not limited to the embodiments presented herein. Method 100 can be employed in many different embodiments or examples not specifically depicted or described herein. In some embodiments, the procedures, the processes, and/or the activities of method 100 can be performed in the order presented. In other embodiments, the procedures, the processes, and/or the activities of method 100 can be performed in any other suitable order. In still other embodiments, one or more of the procedures, the processes, and/or the activities in method 100 can be combined or skipped.

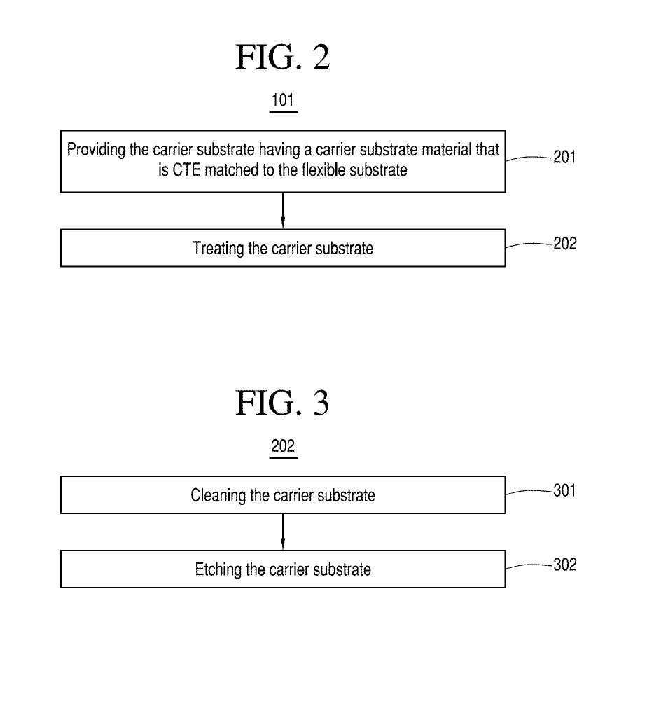

Referring to FIG. 1, method 100 comprises procedure 101 of providing a carrier substrate. The carrier substrate can be a wafer or panel. Accordingly, the carrier substrate comprises a first carrier substrate surface and a second carrier substrate surface opposite the first carrier substrate surface. The carrier substrate can comprise any suitable geometry (e.g., round, rectangular, square, any other suitable polygon, etc.). Likewise, the carrier substrate can comprise any suitable dimensions (e.g., diameter, thickness, length, width, etc.), as applicable. For example, where the carrier substrate is round, the carrier substrate can comprise a diameter of approximately 25 millimeters, 51 millimeters, 76 millimeters, 130 millimeters, 150 millimeters, 200 millimeters, 300 millimeters, 450 millimeters, etc. In these examples, the carrier substrate can also comprise a thickness of greater than or equal to approximately 0.3 millimeters and less than or equal to approximately 1.5 millimeters. Meanwhile, in other examples, where the carrier substrate is rectangular, the carrier substrate can comprise a width and length of 370 millimeters by 470 millimeters, 550 millimeters by 650 millimeters, 1500 millimeters by 1800 millimeters, 2160 millimeters by 2400 millimeters, 2880 millimeters by 3130 millimeters, etc., and where the carrier substrate is square, the carrier substrate can comprise a width and length of 150 millimeters by 150 millimeters, 200 millimeters by 200 millimeters, 300 millimeters by 300 millimeters, etc. In these examples, the carrier substrate can comprise a thickness of less than or equal to approximately 0.3 millimeters and less than or equal to approximately 2.0 millimeters. FIG. 2 illustrates an exemplary procedure 101 of providing the carrier substrate, according to the embodiment of FIG. 1.

Referring to FIG. 2, procedure 101 can comprise process 201 of providing the carrier substrate having a carrier substrate material that is CTE matched to the flexible substrate, described below with respect to procedure 103 (FIG. 1) of method 100 (FIG. 1). For example, the carrier substrate material can comprise alumina, silicon, steel, sapphire, barium borosilicate, soda lime silicate, alkali silicate, or any other suitably CTE matched material. In various more specific examples, the carrier substrate could comprise sapphire with a thickness between approximately 0.7 mm and approximately 1.1 mm. The carrier substrate could also comprise 96% alumina with a thickness between approximately 0.7 mm and approximately 1.1 mm. In a different embodiment, the thickness of the 96% alumina is approximately 2.0 mm. In another example, the carrier substrate could be a single crystal silicon wafer with a thickness of at least approximately 0.65 mm. In still a further embodiment, the carrier substrate could comprise stainless steel with a thickness of at least approximately 0.5 mm. In these or other embodiments, the carrier substrate can comprise any other suitable thickness.

In many embodiments, procedure 101 can also comprise process 202 of treating the carrier substrate. In many embodiments, process 202 can be performed before performing procedure 106. FIG. 3 illustrates an exemplary process 202 of treating the carrier substrate, according to the embodiment of FIG. 1.

In some embodiments, performing procedure 101 can also comprise a process of providing the carrier substrate where the carrier substrate comprises the first adhesive, such as, for example, at the first carrier substrate surface. In these embodiments, process 202 can be omitted (although the carrier substrate could still have been treated before the adhesive was applied thereto).

Referring to FIG. 3, process 202 can comprise activity 301 of cleaning the carrier substrate. Performing activity 301 can comprise cleaning the carrier substrate in a sonic bath (e.g., a megasonic bath, an ultrasonic bath, etc.). In the same or other embodiments, performing activity 301 can also comprise cleaning the carrier substrate with a surfactant solution. For example, the surfactant can be a solution comprised of five percent by volume of a surfactant from Alconox of White Plains, N.Y., sold under the brand “Detergent 8®.” However, the surfactant could also be any other suitable surfactant, such as, for example, a surfactant having properties similar to the Detergent 8® brand. After cleaning the carrier substrate with the surfactant solution, the semiconductor device can be rinsed with deionized water and dried. In some examples, the rinsing can be performed in a quick dump rinser. In these or other examples, the drying can be performed in a spin rinse dryer, such as, for example, where the carrier substrate is round. In still other examples, the drying can be performed by isopropyl alcohol vapor drying and/or air drying the carrier substrate.

Meanwhile, process 202 can also comprise activity 302 of etching the carrier substrate, such as, for example, by ashing the carrier substrate with an oxygen (O₂) plasma. Thus, in some examples, activity 302 can comprise etching the carrier substrate by ashing the carrier substrate in a Tegal 965 asher, manufactured by legal Corporation of Petaluma, Calif., or another suitable device for ashing the carrier substrate. The device for ashing the carrier substrate can be operated at a power level of approximately 250 Watts (or approximately 200-300 Watts). Meanwhile, activity 302 can be performed at a pressure of approximately 0.16 kilopascals (or approximately 0.1-0.2 kilopascals) and/or for a time of approximately 30 minutes (or approximately 15-45 minutes).

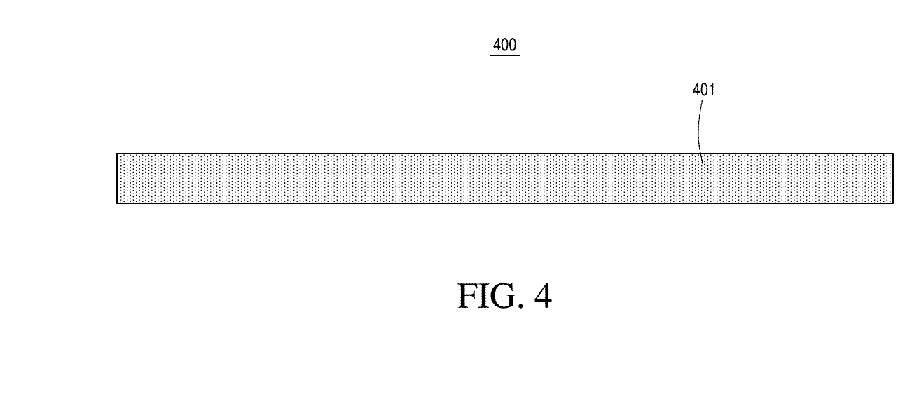

Referring to the drawings, FIG. 4 illustrates a partial cross-sectional view of an exemplary electronic device structure 400 after providing carrier substrate 401, according to the embodiment of FIG. 1. Accordingly, carrier substrate 401 can be similar or identical to the carrier substrate described above with respect to procedure 101 of method 100 (FIG. 1). Electronic device structure 400 can comprise carrier substrate 400.

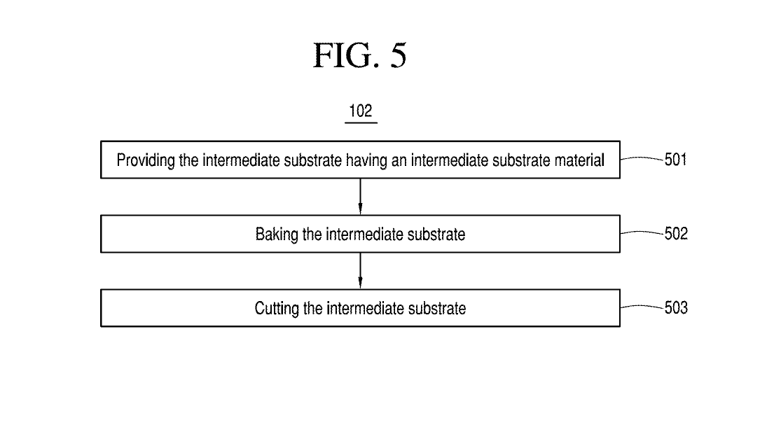

Returning to FIG. 1, method 100 can comprise procedure 102 of providing an intermediate substrate. The intermediate substrate comprises a first intermediate substrate surface and a second intermediate substrate surface opposite the first intermediate substrate surface. The first intermediate substrate surface can be configured to be coupled to the carrier substrate by a first adhesive. In some embodiments, the intermediate substrate can be referred to as a ruggedization film. FIG. 5 illustrates an exemplary procedure 102 of providing the intermediate substrate, according to the embodiment of FIG. 1.

Referring to FIG. 5, procedure 102 can comprise process 501 of providing the intermediate substrate having an intermediate substrate material. In many embodiments, the intermediate substrate material can comprise polyethylene naphthalate, polyethylene terephthalate, polyethersulfone, polyimide, polycarbonate, cyclic olefin copolymer, liquid crystal polymer, any other suitable polymeric material, aluminum foil, mylar, etc. In other embodiments, the intermediate substrate material can comprise tape (e.g., double-sided tape) such as where the intermediate substrate material comprises the first adhesive and/or the second adhesive, as described below.

Procedure 102 can also comprise process 502 of baking the intermediate substrate, such as, for example, with a Yamato oven, manufactured by Yamato Scientific America, Inc. of Santa Clara, Calif., or another suitable device for baking the intermediate substrate without damaging the intermediate substrate. Process 502 can be performed at a preliminary baking condition. The preliminary baking condition can comprise a preliminary baking temperature, a preliminary baking pressure, and/or a preliminary baking time. For example, the preliminary baking temperature can be approximately 200° C. Meanwhile, the preliminary baking pressure can be approximately 0.004 kilopascals (or approximately 0-0.010 kilopascals). Furthermore, the preliminary baking time can be approximately 1 hour. In various embodiments, performing process 502 can comprise an activity of exposing the first intermediate substrate surface and the second intermediate substrate surface to an ionic blower for greater than or equal to approximately 10 seconds prior to baking the intermediate substrate. In some embodiments, process 502 can be omitted.

Procedure 102 can further comprise process 503 of cutting the intermediate substrate. In many embodiments, performing process 503 can comprise sizing the intermediate substrate based on the carrier substrate and/or the flexible substrate. For example, performing process 503 can comprise cutting (e.g., sizing) the intermediate substrate such that the perimeter of the intermediate substrate is offset (e.g., smaller in at least one lateral dimension) from the perimeter of the carrier substrate by greater than or equal to approximately 1.5 millimeters, or 2 millimeters, etc. (or approximately 1-5 millimeters). Likewise, performing process 503 can also comprise cutting (e.g., sizing) the intermediate substrate such that the perimeter of the intermediate substrate is offset (e.g., larger in at least one lateral dimension) than the perimeter of the flexible substrate. Performing process 503 in this manner can aid in performing procedure 112 (FIG. 1) and/or procedure 113 (FIG. 1) later in method 100 (FIG. 1) by distributing stress formed by performing procedure 112 and/or procedure 113. In some embodiments, process 503 can be omitted, such as where intermediate substrate 503 is pre-sized.

In some embodiments, procedure 102 can also comprise a process of providing the intermediate substrate where the first intermediate substrate surface comprises a first adhesive (e.g., where the intermediate substrate comprises tape). In these embodiments, process 502 and/or process 503 can be omitted. In further embodiments, this process can be omitted.

Meanwhile, in the same or other embodiments, procedure 102 can also comprise a process of providing the intermediate substrate where the second intermediate substrate surface comprises a second adhesive (e.g., where the intermediate substrate comprises tape, such as, for example, double-sided tape). In these embodiments, process 502 and/or process 503 can also be omitted. Likewise, in many embodiments, this process can be omitted like the process of providing the intermediate substrate where the first intermediate substrate surface comprises the first adhesive, as described with respect to procedure 101 (FIG. 1).

Referring back to FIG. 1 again, method 100 can comprise procedure 103 of providing a flexible substrate. The term “flexible substrate” as used herein means a free-standing substrate comprising a flexible material which readily adapts its shape. In some embodiments, the flexible substrate can comprise a low elastic modulus. For example, a low elastic modulus can be considered an elastic modulus of less than approximately five gigapascals. In some embodiments, the flexible substrate can comprise a flexible glass material.

The flexible substrate comprises a first flexible substrate surface and a second flexible substrate surface opposite the first flexible substrate surface. The first flexible substrate surface can be configured to be coupled to the second intermediate substrate surface by a second adhesive. Meanwhile, the second flexible substrate surface can be configured such that electronic device(s) are able to be formed over the second flexible substrate surface, such as, for example, when the first intermediate substrate surface is coupled to the carrier substrate and when the first flexible substrate surface is coupled to the second intermediate substrate surface.

In some embodiments, performing procedure 103 can comprise a process of providing the flexible substrate where the flexible substrate comprises a flexible substrate material lacking sufficient mechanical strength to prevent the flexible substrate from being damaged if the flexible substrate were to be coupled to and decoupled from the carrier substrate directly.

Meanwhile, similar to as described above with respect to procedure 101 and/or procedure 102, in some embodiments, performing procedure 103 can comprise a process of providing the flexible substrate where the first flexible substrate surface comprises the second adhesive. In other embodiments, this process can likewise be omitted.

In many embodiments, procedure 103 can comprise a process of treating the flexible substrate. The process can be similar or identical to performing process 202 (FIG. 2) for the carrier substrate. In many examples, this process and process 202 (FIG. 2) can be performed approximately simultaneously with each other, and/or this process can be performed as part of process 202.

Meanwhile, method 100 can comprise procedure 104 of providing the first adhesive. In various embodiments, performing procedure 104 can comprise applying and/or depositing the first adhesive at the first carrier substrate surface and/or the first intermediate substrate surface. In general, procedure 104 can be performed where the first carrier substrate surface and/or the first intermediate substrate surface do not comprise the first adhesive. Performing procedure 104 can comprise applying and/or depositing the first adhesive at the first carrier substrate surface and/or the first intermediate substrate surface according to any suitable technique for applying and/or depositing the first adhesive (e.g., spin-coating, spray-coating, extrusion-coating, preform laminating, slot die coating, screen laminating, screen printing, etc.). For example, performing process 104 can comprise applying and/or depositing the first adhesive at the first carrier substrate surface and/or the first intermediate substrate surface by spin coating the first adhesive at the first carrier substrate surface and/or the first intermediate substrate surface at a rotational speed of approximately 1000 rotations per minute for approximately 25 seconds and/or at a rotational speed of approximately 3500 rotations per minute for approximately 20 seconds. In some embodiments, procedure 104 can be omitted, such as where the first carrier substrate surface and/or the first intermediate substrate surface already comprise the first adhesive.

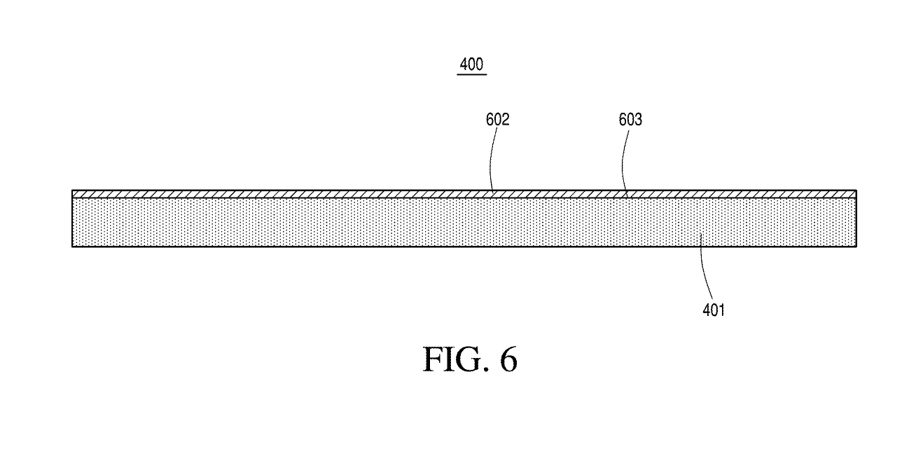

Skipping ahead in the drawings, FIG. 6 illustrates a partial cross-sectional view of electronic device structure 400 (FIG. 4) after applying and/or depositing first adhesive 602 at first carrier substrate surface 603 of carrier substrate 401 (FIG. 4), according to the embodiment of FIG. 1. First adhesive 602 can be similar or identical to the first adhesive described above with respect to procedure 104 (FIG. 1) of method 100 (FIG. 1). Meanwhile, first carrier substrate surface 603 can be similar or identical to the first carrier substrate surface described above with respect to procedure 101 (FIG. 1) of method 100 (FIG. 1). Electronic device structure 400 (FIG. 4) can comprise first adhesive 602, and carrier substrate 401 (FIG. 4) can comprise first carrier substrate surface 603.

Returning again to FIG. 1, method 100 can comprise procedure 105 of providing the second adhesive. In various embodiments, performing procedure 105 can comprise applying and/or depositing the second adhesive at the second intermediate substrate surface and/or the first flexible substrate surface in a similar manner to that of performing procedure 104 for the first adhesive.

In various embodiments, procedure 104 and/or procedure 105 can be performed as part of procedure 106. For example, procedure 104 can be performed prior to performing process 701 and process 702, and procedure 105 can be performed after process 701 but prior to process 702. In a different example, procedure 104 can be performed prior to process 701 and after process 702 while procedure 105 can be performed prior to both process 701 and process 702. In still other examples, procedure 104 and procedure 105 can be performed prior to performing procedure 106, such as where process 701 and process 702 are performed approximately simultaneously with each other.

In some embodiments, the first adhesive and the second adhesive can comprise the same adhesive material, and in other embodiments, the first adhesive and the second adhesive can comprise different adhesive materials. The first adhesive and/or the second adhesive can comprise any suitable adhesive material (e.g., Henkel NS122 adhesive manufactured by Henkel AG & Company, KGaA of Dusseldorf, Germany; EccoCoat 3613 adhesive manufactured by Henkel AG & Company, KGaA of Dusseldorf, Germany; etc.). In these or other embodiments, the adhesive material can comprise a thermally cured adhesive, a pressure sensitive adhesive, an ultraviolet cured adhesive, etc. In many embodiments, the first adhesive can be selected according to the material properties of the carrier substrate and the intermediate substrate. Likewise, the second adhesive can be selected according to the material properties of the intermediate substrate and the flexible substrate. For example, the first adhesive and/or second adhesive can comprise the Henkel NS122 adhesive when the intermediate substrate comprises polyethylene naphthalate or polyethylene terephthalate. Meanwhile, where the intermediate substrate comprises polyimide, the first adhesive and/or the second adhesive can comprise the EccoCoat 3613 adhesive.

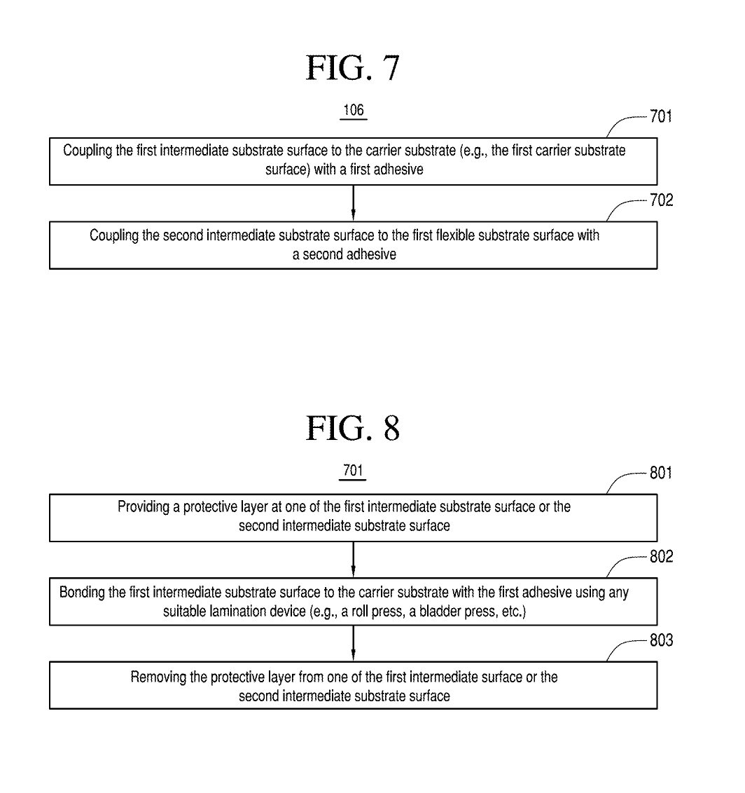

Meanwhile, method 100 can comprise procedure 106 of interposing an intermediate substrate between the carrier substrate and the flexible substrate in order to couple the flexible substrate to the carrier substrate. In some embodiments, performing procedure 106 and/or process 702 can comprise coupling the intermediate substrate to the flexible substrate in order to reinforce the flexible substrate. FIG. 7 illustrates an exemplary procedure 106 of interposing the intermediate substrate between the carrier substrate and the flexible substrate in order to couple the flexible substrate to the carrier substrate, according to the embodiment of FIG. 1.

Referring to FIG. 7, procedure 106 can comprise process 701 of coupling the first intermediate substrate surface to the carrier substrate (e.g., the first carrier substrate surface) with a first adhesive. FIG. 8 illustrates an exemplary process 701.

Referring to FIG. 8, process 701 can comprise activity 801 of providing a protective layer at one of the first intermediate substrate surface or the second intermediate substrate surface. In many embodiments, the protective layer can comprise tape (e.g., Blue Low Tack Squares, product number 18133-7.50, manufactured by Semiconductor Equipment Corporation of Moorpark, Calif.). In many embodiments, performing activity 801 can comprise sizing the protective layer to correspond to the lateral surface area of the first intermediate substrate surface or the second intermediate substrate surface, as applicable.

Performing activity 801 can prevent damage to and/or contamination of the first intermediate substrate surface or the second intermediate substrate surface, as applicable, when performing activity 802. Accordingly, where process 701 is performed prior to process 702, performing activity 801 can comprise providing the protective layer at the second intermediate substrate surface. Alternatively, when process 701 is performed after process 702, performing activity 801 can comprise providing the protective layer at the first intermediate substrate surface. In some embodiments, activity 801 can be omitted.

Meanwhile, process 701 can continue with activity 802 of bonding the first intermediate substrate surface to the carrier substrate with the first adhesive using any suitable lamination device (e.g., a roll press, a bladder press, etc.). In many embodiments, bonding the first intermediate substrate surface to the carrier substrate can occur at a first condition. The first condition can comprise a first pressure, a first temperature, and/or a first feed rate. For example, the first pressure can be greater than or equal to approximately 0 kilopascals (i.e., in a vacuum) and less than or equal to approximately 69 kilopascals (e.g., where the intermediate substrate comprises polyimide) or less than or equal to approximately 150 kilopascals in other embodiments. Furthermore, the first feed rate can be greater than or equal to approximately 0.25 meters per minute and less than or equal to approximately 0.5 meters per minute (or approximately 0.10-1.0 meters per minute). Meanwhile, the first temperature can be greater than or equal to approximately 20° C. and less than or equal to approximately 100° C., 160° C., 220° C., 350° C., etc. For example, the first temperature can be less than or equal to approximately 220° C. (e.g., approximately 100° C.) where the intermediate substrate comprises polyethylene naphthalate and can be less than or equal to approximately 160° C. (e.g., approximately 100° C.) where the intermediate substrate comprises polyethylene terephthalate. Meanwhile, the first temperature can be less than or equal to approximately 350° C. (e.g., approximately 100° C.) where the intermediate substrate comprises polyimide. Generally speaking, the first pressure and/or the first temperature can depend on the material properties and/or limitations of the intermediate substrate.

In some embodiments, process 701 can also comprise activity 803 of removing the protective layer from one of the first intermediate substrate surface or the second intermediate substrate surface. In some embodiments, activity 803 can be omitted, such as, for example, where activity 801 is omitted.

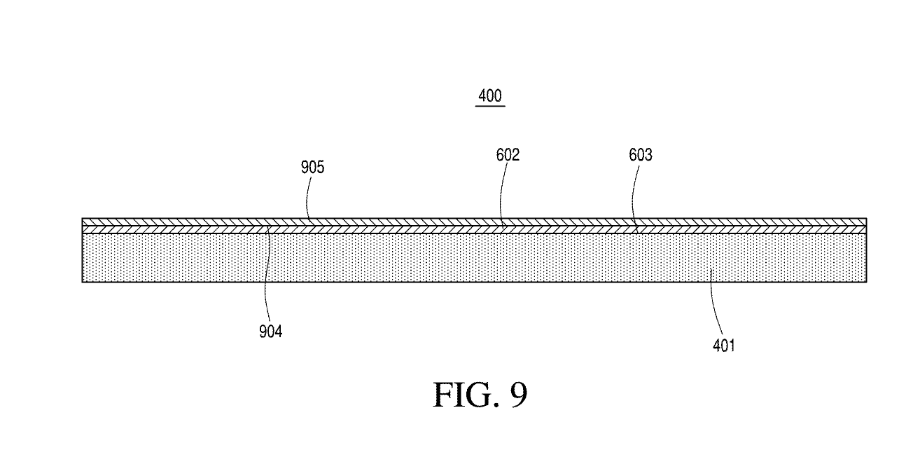

Returning to the drawings, FIG. 9 illustrates a partial cross-sectional view of electronic device structure 400 (FIG. 4) after coupling first intermediate substrate surface 904 of intermediate substrate 905 to first carrier substrate surface 603 (FIG. 6) of carrier substrate 401 with first adhesive 602 (FIG. 6), according to the embodiment of FIG. 1. First intermediate substrate surface 904 and intermediate substrate 905 can be similar or identical to the first intermediate substrate surface and the intermediate substrate described above, respectively, with respect to procedure 102 (FIG. 1) of method 100 (FIG. 1). Electronic device structure 400 (FIG. 4) can comprise intermediate substrate 905, which can comprise first intermediate substrate surface 904.

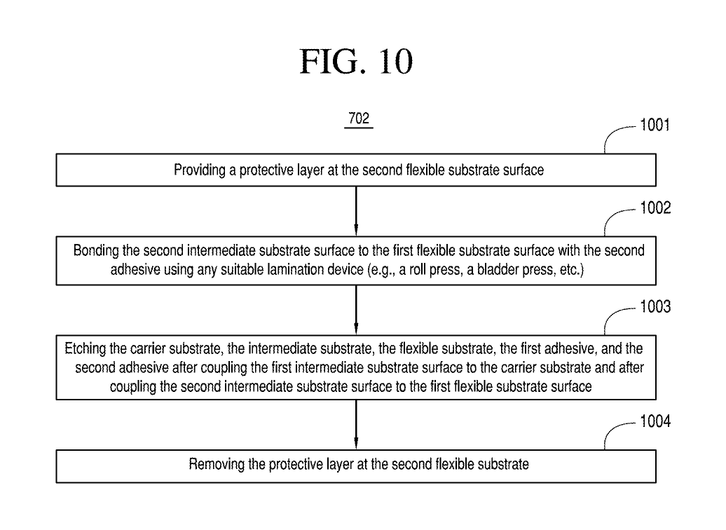

Returning back to FIG. 7, procedure 106 can also comprise process 702 of coupling the second intermediate substrate surface to the first flexible substrate surface with a second adhesive. FIG. 10 illustrates an exemplary process 702.

Referring to FIG. 10, process 702 can comprise activity 1001 of providing a protective layer at the second flexible substrate surface. The protective layer can be similar or identical to the protective layer described above with respect to activity 801 (FIG. 8).

Process 702 can continue with activity 1002 of bonding the second intermediate substrate surface to the first flexible substrate surface with the second adhesive using any suitable lamination device (e.g., a roll press, a bladder press, etc.). In many embodiments, bonding the second intermediate substrate surface to the first flexible substrate surface occurs at a second condition. The second condition can be similar or identical to the first condition described above with respect to activity 802 (FIG. 8). Accordingly, in some embodiments, the first condition and the second condition can be the same while in other embodiments, the first condition and second condition can be different. For example, the second condition can comprise a second pressure, which can be greater than or equal to approximately 0 kilopascals (i.e., in a vacuum) and less than or equal to approximately 128 kilopascals (or less than or equal to approximately 150 kilopascals). In more specific examples, where the intermediate substrate comprises polyimide, the second pressure can be less than or equal to approximately 69 kilopascals, and where the intermediate substrate comprises polyethylene naphthalate or polyethylene terephthalate, the second pressure can be less than or equal to approximately 128 kilopascals).

Process 702 can further comprise activity 1003 of etching the carrier substrate, the intermediate substrate, the flexible substrate, the first adhesive, and the second adhesive after coupling the first intermediate substrate surface to the carrier substrate and after coupling the second intermediate substrate surface to the first flexible substrate surface. In some embodiments, performing activity 1003 can comprise ashing the carrier substrate, the intermediate substrate, the flexible substrate, the first adhesive, and the second adhesive with a Tegal 901 asher, manufactured by Tegal Corporation of Petaluma, Calif., or another suitable device for ashing the carrier substrate, the intermediate substrate, the flexible substrate, the first adhesive, and the second adhesive. Activity 1003 can be performed for greater than or equal to approximately 900 seconds. In many embodiments, performing activity 1003 can remove excess of the first adhesive and/or the second adhesive.

In some embodiments, activity 1003 can be performed as part of process 701 (FIG. 7) instead of process 702 (FIG. 7). For example, activity 1003 can be performed as part of process 701 (FIG. 7) where process 701 is performed after process 702 (FIG. 7). Still, in many embodiments, activity 1003 can be performed after activity 1001 and activity 1002 and can be performed before activity 1004. Meanwhile, in still further embodiments, activity 1003 can be performed after procedure 107 (FIG. 1). In still other embodiments, activity 1003 can be omitted, such as where the intermediate substrate comprises polyimide.

In some embodiments, process 702 can also comprise activity 1004 of removing the protective layer at the second flexible substrate. In some embodiments, where process 701 is performed after process 702, activity 1004 can be performed after process 701 is performed.

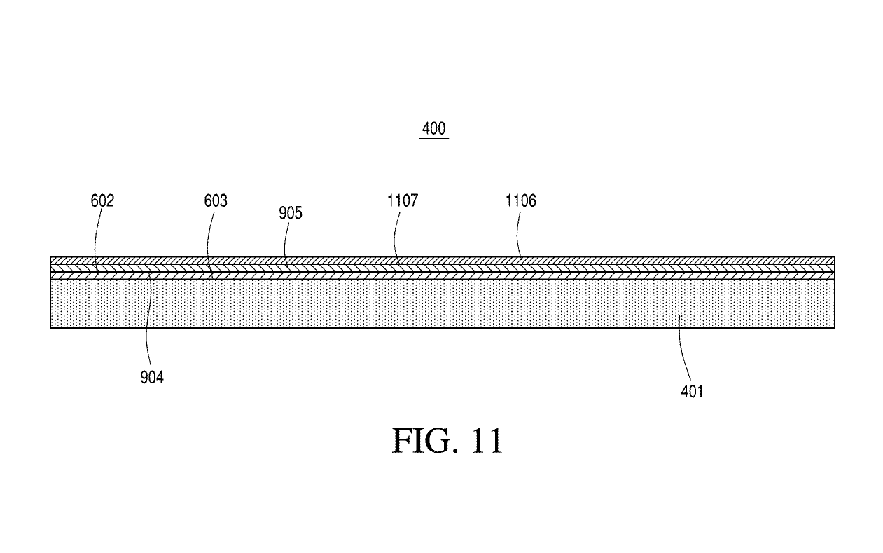

Returning again to the drawings, FIG. 11 illustrates a partial cross-sectional view of electronic device structure 400 (FIG. 4) after applying and/or depositing second adhesive 1106 at second intermediate substrate surface 1107 of intermediate substrate 905 (FIG. 9) and after coupling first intermediate substrate surface 904 (FIG. 9) of intermediate substrate 905 to first carrier substrate surface 603 (FIG. 6) of carrier substrate 401 with first adhesive 602 (FIG. 6), according to the embodiment of FIG. 1. Electronic device structure 400 (FIG. 4) can comprise second adhesive 1106, and intermediate substrate 905 (FIG. 9) can comprise second intermediate substrate surface 1107.

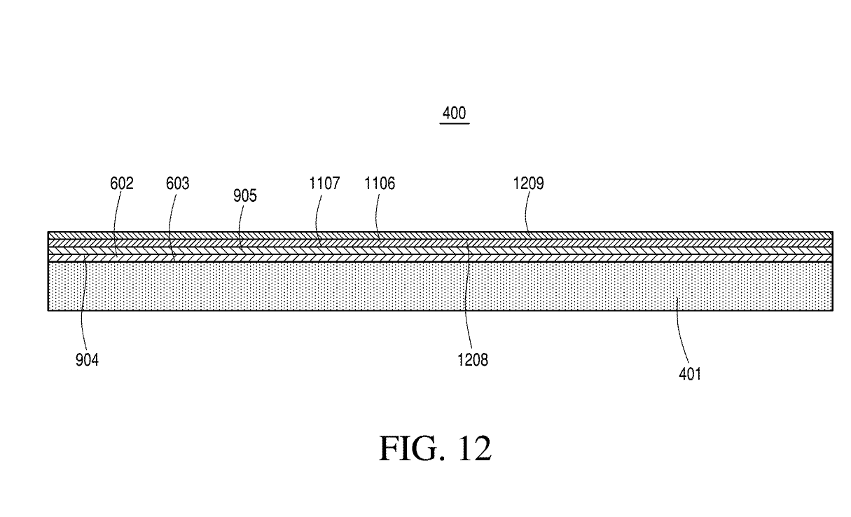

Meanwhile, FIG. 12 illustrates a cross-sectional view of electronic device structure 400 (FIG. 4) after coupling second intermediate substrate surface 1107 (FIG. 11) to first flexible substrate surface 1208 of flexible substrate 1209 with second adhesive 1106 (FIG. 11), after applying and/or depositing second adhesive 1106 at second intermediate substrate surface 1107 of intermediate substrate 905 (FIG. 9), and after coupling first intermediate substrate surface 904 (FIG. 9) of intermediate substrate 905 to first carrier substrate surface 603 (FIG. 6) of carrier substrate 401 with first adhesive 602 (FIG. 6), according to the embodiment of FIG. 1. First flexible substrate surface 1208 and flexible substrate 1209 can be similar or identical to the first flexible substrate surface and the flexible substrate described above, respectively, with respect to procedure 103 (FIG. 1) of method 100 (FIG. 1). Electronic device structure 400 (FIG. 4) can comprise flexible substrate 1209, which can comprise first flexible substrate surface 1208.

Although FIGS. 6, 9, 11, and 12 illustrate performing method 100 in such a manner that process 701 (FIG. 7) is performed prior to process 702 (FIG. 7), in some embodiments, process 702 (FIG. 7) can be performed after performing process 701 (FIG. 7) instead. Meanwhile, in other embodiments, process 701 (FIG. 7) and process 702 (FIG. 7) can be performed approximately simultaneously.

Returning now to FIG. 1, method 100 can comprise procedure 107 of curing the first adhesive and the second adhesive after coupling the first intermediate substrate surface to the carrier substrate and after coupling the second intermediate substrate surface to the first flexible substrate surface. Performing procedure 107 can comprise curing the first adhesive and the second adhesive according to any technique and/or combination of techniques suitable for curing the first adhesive and/or the second adhesive (e.g., ultraviolet curing, heat curing, pressure curing, etc.) without damaging the carrier substrate, the intermediate substrate, or the flexible substrate. For example, where the first adhesive and/or the second adhesive comprise Henkel NS122 adhesive, performing procedure 107 can comprise ultraviolet curing the first adhesive and/or the second adhesive using an ultraviolet cure system, such as, for example, a Dymax ultraviolet cure system manufactured by Dymax Corporation of Torrington, Conn. In these embodiments, procedure 107 can be performed for greater than or equal to approximately 20 seconds (or approximately 10-30 seconds). Meanwhile, where the first adhesive and/or the second adhesive comprise the EccoCoat 3613 adhesive, performing procedure 107 can comprise heat curing the first adhesive and/or the second adhesive in an oven, such as, for example, a Yamato Oven manufactured by Yamato Scientific America, Inc. of Santa Clara, Calif. In these embodiments, procedure 107 can be performed at a temperature of approximately 150° C. (or approximately 200° C.) for greater than or equal to approximately 30 minutes (or approximately 20-40 minutes).

Method 100 can comprise procedure 108 of cleaning the carrier substrate, the intermediate substrate, the flexible substrate, the first adhesive, and the second adhesive. Procedure 108 can be similar to activity 301 (FIG. 3). In many embodiments, procedure 108 can be performed after procedure 106 and/or procedure 107. In other embodiments, procedure 108 can be omitted, such as where the intermediate substrate comprises polyimide.

Method 100 can comprise procedure 109 of baking the carrier substrate, the intermediate substrate, the flexible substrate, the first adhesive, and the second adhesive. Procedure 109 can be similar to process 502 (FIG. 5). In many embodiments, procedure 109 can be performed after procedure 108.

Method 100 can also comprise procedure 110 of cleaning the carrier substrate, the intermediate substrate, the flexible substrate, the first adhesive, and the second adhesive. Procedure 110 can be similar to activity 301 (FIG. 3). In many embodiments, procedure 110 can be performed after procedure 109.

Method 100 can additionally comprise procedure 111 of drying the carrier substrate, the intermediate substrate, the flexible substrate, the first adhesive, and the second adhesive. In some embodiments, procedure 111 can comprise drying the carrier substrate, the intermediate substrate, the flexible substrate, the first adhesive, and the second adhesive in an oven, such as, for example, with a Yamato Oven, manufactured by Yamato Scientific America, Inc. of Santa Clara, Calif., or another suitable device for baking the intermediate substrate. Process 502 can be performed at a dry baking condition. The dry baking condition can comprise a dry baking temperature (e.g., approximately 80-120° C., for example, approximately 100° C.) and/or a dry baking time (e.g., greater than or equal to approximately 1 hours and less than or equal to approximately 4 hours, for example, approximately 3 hours). In many embodiments, procedure 111 can be performed after procedure 110. Procedure 111 can also comprise cooling and/or permitting to cool the carrier substrate, the intermediate substrate, the flexible substrate, the first adhesive, and the second adhesive for greater than or equal to approximately 30 minutes. Performing procedure 111 can remove moisture from and/or outgas the carrier substrate, the intermediate substrate, the flexible substrate, the first adhesive, and the second adhesive. Accordingly, the length of the dry baking time can depend on the materials used for the carrier substrate, the intermediate substrate, the flexible substrate, the first adhesive, and/or the second adhesive as well as the out-gassing rate and/or out-diffusion rate of the carrier substrate, the intermediate substrate, the flexible substrate, the first adhesive, and the second adhesive.

Method 100 can further comprise procedure 112 of depositing a nitride barrier layer over the second flexible substrate surface. Procedure 112 can comprise depositing the nitride barrier to a nitride barrier thickness of approximately 0.3 micrometers (or approximately 0.2-0.5 micrometers). In many embodiments, procedure 112 can be performed after procedure 111.

Method 100 can also comprise procedure 113 of inspecting the carrier substrate, the intermediate substrate, the flexible substrate, the first adhesive, and the second adhesive, such as, for example, to determine if any of the carrier substrate, the intermediate substrate, and/or the flexible substrate are damaged. In some embodiments, procedure 113 can be omitted. Procedure 113 can be performed after procedure 112.

Method 100 can comprise procedure 114 of forming one or more electronic devices over the second flexible substrate surface. The electronic device(s) can comprise one or more electronic sensors, one or more electronic displays, one or more electronic transistors (e.g., thin film transistors), one or more electronic diodes, one or more micro-electromechanical systems, or any other suitable electronic device(s). In many embodiments, procedure 114 can be performed after performing procedures 101 through 113.

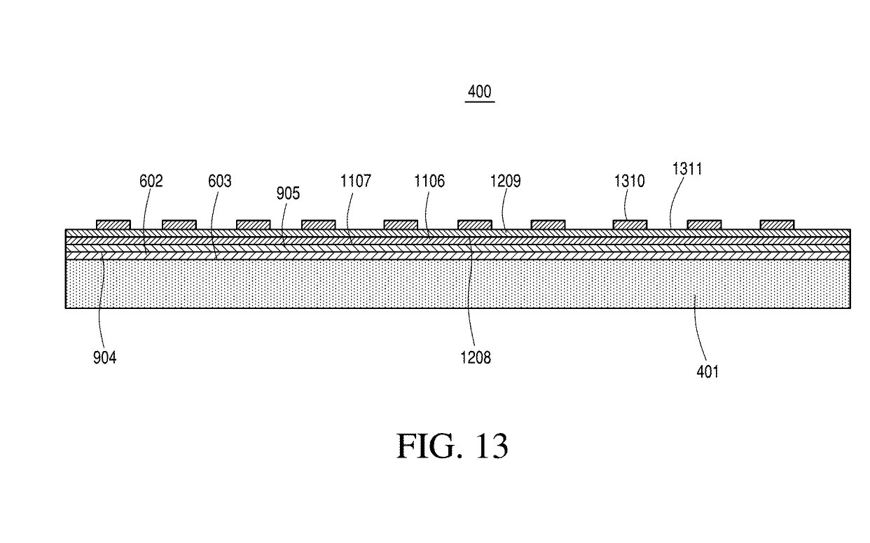

FIG. 13 illustrates a cross-sectional view of electronic device structure 400 (FIG. 4) after interposing intermediate substrate 905 (FIG. 9) between carrier substrate 401 (FIG. 4) and flexible substrate 1209 and after forming electronic device(s) 1310 over second flexible substrate surface 1311, according to the embodiment of FIG. 1. Electronic device structure 400 (FIG. 4) can comprise electronic device(s) 1310, and flexible substrate 1209 (FIG. 12) can comprise second flexible substrate surface 1311.

Returning to FIG. 1, method 100 can further comprise procedure 115 of decoupling the first intermediate substrate surface from the carrier substrate (e.g., the first carrier substrate surface). The intermediate substrate can be configured to substantially relieve stress formed at the flexible substrate when the flexible substrate is decoupled from the carrier substrate. Accordingly, performing procedure 115 can comprise substantially relieving stress formed at the flexible substrate with the intermediate layer while the flexible substrate is being decoupled from the carrier substrate. Substantially relieving stress formed at the flexible substrate can refer to relieving sufficient stress to prevent damage to the flexible substrate and/or the electronic device(s) when performing procedure 115. As a result, method 100 can permit one or more electronic devices (e.g., the electronic device(s) described above with respect to procedure 114) to be manufactured on flexible substrates (e.g., the flexible substrate described above with respect to procedure 103) coupled to one or more respective rigid carrier substrates (e.g., the carrier substrate described above with respect to procedure 101) in order to permit using electronic device manufacturing equipment and/or techniques configured for use with rigid substrates while avoiding damage to the flexible substrate(s) by interposing one or more respective intermediate substrates between the rigid carrier substrate(s) and the flexible substrate(s) to absorb stress when decoupling the flexible substrate(s) from the carrier substrate(s).

In many embodiments, procedure 115 can comprise mechanically decoupling the first intermediate substrate surface from the carrier substrate. For example, in these embodiments, procedure 115 can comprise inserting a tool (e.g., a bladed edge) at the first intermediate substrate surface (e.g., between the first adhesive and the first intermediate substrate surface) and pushing the tool along the first intermediate substrate surface at an angle greater than or equal to approximately 0 degrees and less than or equal to approximately 45 degrees with respect to the first intermediate substrate surface in order to release the first intermediate substrate surface from the carrier substrate.

In other embodiments, procedure 115 can comprise decoupling the first intermediate substrate surface from the carrier substrate according to any other suitable technique (e.g., chemical, laser, ultraviolet, thermal, etc.) for decoupling the first intermediate substrate surface from the carrier substrate. Accordingly, any suitable debonding techniques described in United States Patent Publication Serial No. 20100297829, United States Patent Publication Serial No. 20110023672, United States Patent Publication Serial No. 20110064953, United States Patent Publication Serial No. 20110228492, the technical paper of S. M. O'Rourke, et al., Direct Fabrication of a-Si:H Thin Film Transistor Arrays on Plastic and Metal Foils for Flexible Displays, ADM002187, Proceedings of the Army Science Conference (26^{th}), pp. 1-4, December 2008, and the technical paper of Satoshi Inoue, et al., Surfac-Free Technology by Laser Annealing (SUFTLA) and Its Application to Poly-Si TFT-LCDs on Plastic Film With Integrated Drivers, IEEE Transactions on Electron Devices, Vol. 49, No. 8, pp. 1353-1360, August 2002, each of which is incorporated by reference herein, can be used to perform procedure 115.

In many embodiments, procedure 115 can be performed in such a manner that the first adhesive remains with the carrier substrate. However, in some embodiments, the first intermediate substrate surface can be etched in a manner similar to activity 302 (FIG. 3) to remove any residuals of the first adhesive at the first intermediate substrate surface.

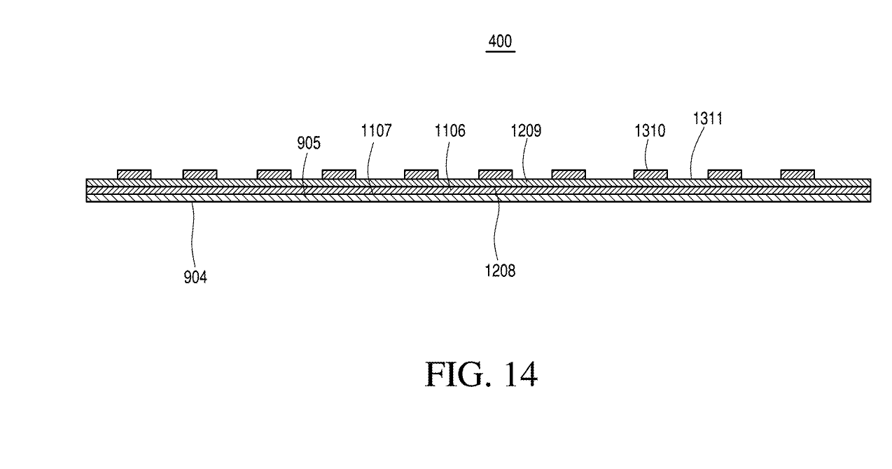

FIG. 14 illustrates a cross-sectional view of electronic device structure 400 (FIG. 4) after forming electronic device(s) 1310 (FIG. 13) over second flexible substrate surface 1208 (FIG. 12) and after decoupling first intermediate substrate surface 904 (FIG. 9) of intermediate substrate 905 (FIG. 9) from carrier substrate 401 (FIG. 4), according to the embodiment of FIG. 1.

Returning again to FIG. 1, after performing procedure 115, method 100 can also comprise procedure 116 of decoupling the second intermediate substrate surface from the first flexible substrate surface. The intermediate substrate can be configured to be decoupled from the carrier substrate and the flexible substrate without damaging the electronic device(s). Meanwhile, in some embodiments, procedure 116 can be omitted, and the intermediate substrate can remain coupled to the flexible substrate by the second adhesive in order to reinforce the flexible substrate.

Notwithstanding those embodiments where it is desirable to leave the intermediate substrate coupled to the flexible substrate, procedure 116 can comprise mechanically decoupling the second intermediate substrate surface from the first flexible substrate surface. For example, mechanically decoupling the second intermediate substrate surface from the first flexible substrate surface can comprise manually pulling the intermediate substrate away from the flexible substrate with a continuous force and at a low angle (e.g., approximately 5-45 degrees) with respect to the flexible substrate in order to release the second intermediate substrate surface form the first flexible substrate surface. In these examples, procedure 116 can comprise providing a protective layer over the second flexible substrate surface to protect any electronic device(s) formed thereon while performing procedure 116.

Meanwhile, procedure 116 can also comprise decoupling the second intermediate substrate surface from the first flexible substrate surface according to any other suitable technique (e.g., chemical, laser, ultraviolet, thermal, etc.) for decoupling the first intermediate substrate surface from the carrier substrate. Accordingly, procedure 116 can be similar or identical to procedure 115.

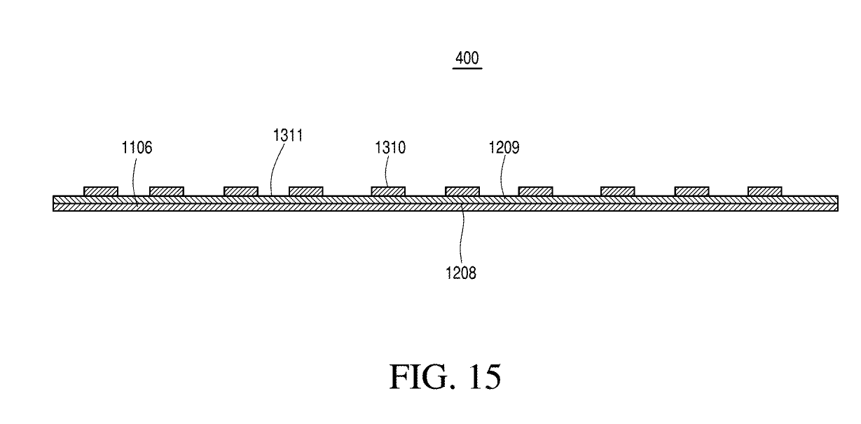

FIG. 15 illustrates a cross-sectional view of electronic device structure 400 (FIG. 4) after forming electronic device(s) 1310 (FIG. 13) over second flexible substrate surface 1208 (FIG. 12), after decoupling first intermediate substrate surface 904 (FIG. 9) of intermediate substrate 905 (FIG. 9) from carrier substrate 401 (FIG. 4), and after decoupling second intermediate substrate surface 1107 (FIG. 11) from first flexible substrate surface 1208 (FIG. 12) of flexible substrate 1209 (FIG. 12), according to the embodiment of FIG. 1.

In some embodiments, procedure 116 can further comprise etching the flexible substrate in a manner similar to activity 302 (FIG. 3) to remove any residuals of the second adhesive at the first flexible substrate surface. Accordingly, etching the flexible substrate can be performed after decoupling the second intermediate substrate surface from the first flexible substrate surface.

In many embodiments, procedure 102 through procedure 116 can be performed for both sides of the carrier substrate of procedure 101 of method 100. In these embodiments, one or more of procedure 102 through procedure 116 can be performed approximately simultaneously for both sides of the carrier substrate. Meanwhile, in these or other embodiments, one or more of procedure 102 through procedure 116 can be repeated and performed separately for each side of the carrier substrate.

Although the invention has been described with reference to specific embodiments, it will be understood by those skilled in the art that various changes may be made without departing from the spirit or scope of the invention. Accordingly, the disclosure of embodiments of the invention is intended to be illustrative of the scope of the invention and is not intended to be limiting. It is intended that the scope of the invention shall be limited only to the extent required by the appended claims. For example, to one of ordinary skill in the art, it will be readily apparent that procedures 101-116 of FIG. 1, processes 201 and 202 of FIG. 2, activities 301 and 302 of FIG. 3, processes 501-503 of FIG. 5, processes 701 and 702 of FIG. 7, activities 801 through 803 of FIG. 8, and activities 1001 through 1004 of FIG. 10 may be comprised of many different procedures, processes, and activities and be performed by many different modules, in many different orders, that any element of FIGS. 1-15 may be modified, and that the foregoing discussion of certain of these embodiments does not necessarily represent a complete description of all possible embodiments.

All elements claimed in any particular claim are essential to the embodiment claimed in that particular claim. Consequently, replacement of one or more claimed elements constitutes reconstruction and not repair. Additionally, benefits, other advantages, and solutions to problems have been described with regard to specific embodiments. The benefits, advantages, solutions to problems, and any element or elements that may cause any benefit, advantage, or solution to occur or become more pronounced, however, are not to be construed as critical, required, or essential features or elements of any or all of the claims, unless such benefits, advantages, solutions, or elements are expressly stated in such claim.

Moreover, embodiments and limitations disclosed herein are not dedicated to the public under the doctrine of dedication if the embodiments and/or limitations: (1) are not expressly claimed in the claims; and (2) are or are potentially equivalents of express elements and/or limitations in the claims under the doctrine of equivalents.

What is claimed is:

1) A method comprising:
providing a carrier substrate;
providing an intermediate substrate comprising a first intermediate substrate surface and a second intermediate substrate surface opposite the first intermediate substrate surface;
providing a flexible substrate comprising a first flexible substrate surface and a second flexible substrate surface opposite the first flexible substrate surface;
coupling the first intermediate substrate surface to the carrier substrate with a first adhesive; and
coupling the second intermediate substrate surface to the first flexible substrate surface with a second adhesive.

2) The method of claim 1 further comprising at least one of:
providing the first adhesive at one or both of the carrier substrate and the first intermediate substrate surface; or
providing the second adhesive at one or both of the second intermediate substrate surface and the first flexible substrate surface.

3) The method of claim 1 wherein at least one of:
the first adhesive comprises an adhesive material, and the second adhesive comprises the adhesive material;
providing the carrier substrate comprises providing the carrier substrate having a carrier substrate material comprising at least one of alumina, silicon, steel, sapphire, barium borosilicate, soda lime silicate, or alkali silicate;
providing the flexible substrate comprises providing the flexible substrate having a flexible glass material;
providing the intermediate substrate comprises providing the intermediate substrate having an intermediate substrate material comprising at least one of polyethylene naphthalate, polyethylene terephthalate, polyethersulfone, polyimide, polycarbonate, cyclic olefin copolymer, or liquid crystal polymer;
providing the carrier substrate comprises treating the carrier substrate before coupling the first intermediate substrate surface to the carrier substrate, wherein treating the carrier substrate comprises at least one of:
cleaning the carrier substrate; or
ashing the carrier substrate;
or
baking the carrier substrate, the intermediate substrate, the flexible substrate, the first adhesive, and the second adhesive after coupling the first intermediate substrate surface to the carrier substrate and after coupling the second intermediate substrate surface to the first flexible substrate surface.

4) The method of claim 1 wherein at least one of:
coupling the first intermediate substrate surface to the carrier substrate with the first adhesive comprises bonding the first intermediate substrate surface to the carrier substrate with the first adhesive using at least one of a roll press or a bladder press;
or
coupling the second intermediate substrate surface to the first flexible substrate surface with the second adhesive comprises bonding the second intermediate substrate surface to the first flexible substrate surface with the second adhesive using the at least one of the roll press or the bladder press.

5) The method of claim 4 wherein at least one of:
bonding the first intermediate substrate surface to the carrier substrate occurs at a first condition comprising at least one of:
a first pressure greater than or equal to approximately 0 kilopascals and less than or equal to approximately 69 kilopascals;
a first temperature greater than or equal to approximately 20° C. and less than or equal to approximately 100° C.; or
a first feed rate greater than or equal to approximately 0.25 meters per minute and less than or equal to approximately 0.5 meters per minute;
or
bonding the second intermediate substrate surface to the first flexible substrate surface occurs at a second condition comprising at least one of:
a second pressure greater than or equal to approximately 0 kilopascals and less than or equal to approximately 138 kilopascals;
a second temperature greater than or equal to approximately 20° C. and less than or equal to approximately 100° C.; or
a second feed rate greater than or equal to approximately 0.25 meters per minute and less than or equal to approximately 0.5 meters per minute.

6) The method of claim 1 wherein:
providing the intermediate substrate comprises at least one of:
baking the intermediate substrate at a preliminary baking condition comprising at least one of:
a preliminary baking temperature of approximately 200° C.;
a preliminary baking pressure of approximately 0.004 kilopascals; or
a preliminary baking time of approximately 1 hour;
or
cutting the intermediate substrate, wherein cutting the intermediate substrate comprises sizing the intermediate substrate based on a size of at least one of the carrier substrate or the flexible substrate.

7) The method of claim 1 further comprising:
forming one or more electronic devices over the second flexible substrate surface after coupling the first intermediate substrate surface to the carrier substrate and after coupling the second intermediate substrate surface to the first flexible substrate surface.

8) The method of claim 7 further comprising:
after coupling the first intermediate substrate surface to the carrier substrate and after coupling the second intermediate substrate surface to the first flexible substrate surface, decoupling the first intermediate substrate surface from the carrier substrate.

9) The method of claim 8 further comprising:
after coupling the first intermediate substrate surface to the carrier substrate and after coupling the second intermediate substrate surface to the first flexible substrate surface, decoupling the second intermediate substrate surface from the first flexible substrate surface after decoupling the first intermediate substrate from the carrier substrate.

10) A method of providing one or more electronic devices, the method comprising:
providing a carrier substrate;
providing a flexible substrate; and
interposing a ruggedization film between the carrier substrate and the flexible substrate in order to couple the flexible substrate to the carrier substrate, the ruggedization film being configured to substantially relieve stress formed at the flexible substrate when the flexible substrate is decoupled from the carrier substrate.

11) The method of claim 10 wherein:
interposing the ruggedization film between the carrier substrate and the flexible substrate comprises:
coupling a first ruggedization film surface of the ruggedization film to the carrier substrate with a first adhesive, further wherein one of: (a) at least one of the carrier substrate or the first ruggedization film surface comprises the first adhesive, or (b) coupling the first ruggedization film surface to the carrier substrate comprises at least one of providing the first adhesive at the carrier substrate or providing the first adhesive at the first ruggedization film surface; and
coupling a second ruggedization film surface of the ruggedization film to a first flexible substrate surface of the flexible substrate with a second adhesive after coupling the first ruggedization film surface to the carrier substrate, the second ruggedization film surface being opposite to the first ruggedization film surface, further wherein one of: (a) at least one of the second ruggedization film surface or the first flexible substrate surface comprises the second adhesive, or (b) coupling the second ruggedization film surface to the first flexible substrate surface comprises at least one of providing the second adhesive at the second ruggedization film surface or providing the second adhesive at the first flexible substrate surface.

12) The method of claim 11 further comprising:
forming the one or more electronic devices over a second flexible substrate surface of the flexible substrate, the second flexible substrate surface being opposite to the first flexible substrate surface.

13) The method of claim 10 wherein:
interposing the ruggedization film between the carrier substrate and the flexible substrate comprises:
coupling a second ruggedization film surface of the ruggedization film to a first flexible substrate surface of the flexible substrate with a second adhesive, further wherein one of: (a) at least one of the second ruggedization film surface or the first flexible substrate surface comprises the second adhesive or (b) coupling the second ruggedization film surface to the first flexible substrate surface comprises at least one of providing the second adhesive at the second ruggedization film surface or providing the second adhesive at the first flexible film surface; and
coupling a first ruggedization film surface of the ruggedization film to the carrier substrate with a second adhesive after coupling the second ruggedization film surface to the first flexible substrate substrate, the first ruggedization film surface being opposite to the second ruggedization film surface, further wherein one of: (a) at least one of the first ruggedization film surface or the carrier substrate comprises the second adhesive or (b) coupling the first ruggedization film surface to the carrier substrate comprises at least one of providing the first adhesive at the first ruggedization film surface or providing the first adhesive at the carrier substrate.

14) The method of claim 10 wherein:
interposing the ruggedization film between the carrier substrate and the flexible substrate comprises:
coupling a first ruggedization film surface of the ruggedization film to the carrier substrate with a first adhesive, further wherein one of: (a) at least one of the carrier substrate or the first ruggedization film surface comprises the first adhesive or (b) coupling the first ruggedization film surface to the carrier substrate comprises at least one of providing the first adhesive at the carrier substrate or providing the first adhesive at the first ruggedization film surface;
coupling a second ruggedization film surface of the ruggedization film to a first flexible substrate surface of the flexible substrate with a second adhesive, the second ruggedization film surface being opposite to the first ruggedization film surface, further wherein one of: (a) at least one of the second ruggedization film surface or the first flexible substrate surface comprises the second adhesive or (b) coupling the second ruggedization film surface to the first flexible substrate surface comprises at least one of providing the second adhesive at the second ruggedization film surface or providing the second adhesive at the first flexible substrate surface;
and
coupling the first ruggedization film surface to the carrier substrate and coupling the second ruggedization film surface to the first flexible substrate surface occur approximately simultaneously with each other.

15) The method of claim 10 wherein:
interposing the ruggedization film between the carrier substrate and the flexible substrate comprises coupling the ruggedization film to the flexible substrate in order to reinforce the flexible substrate.

16) The method of claim 10 further comprising:
decoupling the first ruggedization film surface from the carrier substrate after interposing the ruggedization film between the carrier substrate and the flexible substrate; and
substantially relieving stress formed at the flexible substrate with the ruggedization film while the flexible substrate is being decoupled from the carrier substrate.

17) An electronic device structure, the electronic device structure comprising:
an intermediate substrate comprising a first intermediate substrate surface and a second intermediate substrate surface opposite the first intermediate substrate surface, the first intermediate substrate surface being configured to be coupled to a carrier substrate by a first adhesive; and
a flexible substrate comprising a first flexible substrate surface and a second flexible substrate surface opposite the first flexible substrate surface, the first flexible substrate surface being configured to be coupled to the second intermediate substrate surface by a second adhesive and the second flexible substrate surface being configured such that one or more electronic devices are able to be formed over the second flexible substrate surface when the first intermediate substrate surface is coupled to the carrier substrate and when the first flexible substrate surface is coupled to the second intermediate substrate surface;
wherein:
the intermediate substrate is configured to be decoupled from the carrier substrate and the flexible substrate without damaging the one or more electronic devices or the flexible substrate.

18) The electronic device structure of claim 17 further comprising at least one of:
at least part of the first adhesive; or
the second adhesive;
wherein:
the first adhesive comprises one of Henkel NS122 adhesive, EccoCoat 3613 adhesive, or a pressure sensitive adhesive; and
the second adhesive comprises the one of the Henkel NS 122 adhesive, the EccoCoat 3613 adhesive, or the pressure sensitive adhesive.

19) The electronic device structure of claim 17 wherein at least one of:
the carrier substrate comprises at least one of alumina, silicon, steel, sapphire, barium borosilicate, soda lime silicate, or alkali silicate;
the flexible substrate comprises a flexible glass material; or
the intermediate substrate comprises at least one of polyethylene naphthalate, polyethylene terephthalate, polyethersulfone, polyimide, polycarbonate, cyclic olefin copolymer, or liquid crystal polymer.

20) The electronic device structure of claim 17 further comprising at least one of:
a nitride barrier layer between the second flexible substrate surface and the one or more electronic devices; or
the one or more electronic devices over the second flexible substrate surface.
